(19) United States
(12) Patent Application Publication
(10) Pub. No.: US 2026/0255664 A1
(43) Pub. Date: Aug. 27, 2026

(54) GATE DIELECTRICS OF NANOSTRUCTURE TRANSISTORS AND THE METHODS OF FORMING THE SAME

(71) Applicant: Taiwan Semiconductor Manufacturing Co., Ltd., Hsinchu (TW)

(72) Inventors: Kuei-Lun Lin, Keelung City (TW); Yen-Fu Chen, Taipei (TW); Tsung-Da Lin, Hsinchu (TW); Chi On Chui, Hsinchu (TW)

(21) Appl. No.: 19/240,625

(22) Filed: Jun. 17, 2025

Related U.S. Application Data
(60) Provisional application No. 63/763,694, filed on Feb. 26, 2025.

(51) Int. Cl. H10D 84/83; H01L 21/02; H10D 30/00; H10D 30/01; H10D 30/43; H10D 62/10; H10D 62/13; H10D 64/27; H10D 64/68; H10D 84/01

(52) U.S. Cl. CPC H10D 84/832; H10D 30/014; H10D 30/0191; H10D 30/43; H10D 30/502; H10D 62/102; H10D 62/121; H10D 62/151; H10D 64/516; H10D 64/685; H10D 64/691; H10D 84/0144; H10P 14/6339

(57) ABSTRACT

A method includes forming a plurality of semiconductor nanostructures comprising a lower semiconductor nanostructure and a topmost semiconductor nanostructure over the lower semiconductor nanostructure, forming interfacial layers contacting the plurality of semiconductor nanostructures, and depositing high-k dielectric layers encircling the interfacial layers. A topmost high-k dielectric layer of the high-k dielectric layers encircling the topmost semiconductor nanostructure includes a topmost horizontal portion overlapping the topmost semiconductor nanostructure, a bottom horizontal portion overlapped by the topmost semiconductor nanostructure, and a sidewall portion on a sidewall of the topmost semiconductor nanostructure. A first one of the topmost horizontal portion, the bottom horizontal portion, and the sidewall portion has a first thickness. A second one of the topmost horizontal portion, the bottom horizontal portion, and the sidewall portion has a second thickness smaller than the first thickness.

### PRIORITY CLAIM AND CROSS-REFERENCE

This application claims the benefit of the following provisionally filed U.S. Patent application: Application No. 63/763,694, filed on Feb. 26, 2025, and entitled “Gate Oxide Thickness Modulation,” which application is hereby incorporated herein by reference.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs, and for these advances to be realized, similar developments in IC processing and manufacturing are needed. For example, Gate-All-Around (GAA) Transistors have been introduced to replace planar transistors. The structures of the GAÅ transistors and methods of fabricating the GAÅ transistors are being developed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 11A, 11B, 12-28, 29A, 29B, 29C, 30A, and 30B illustrate the views of intermediate stages in the formation of nanostructure transistors in accordance with some embodiments.

FIGS. 31-33 illustrate the effects of the modulated gate oxide thicknesses on the performance of nanostructure transistors in accordance with some embodiments.

FIG. 34 illustrates a process flow for forming a nanostructure transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Nanostructure transistors (also referred to as or nanosheet transistors or Gate All-Around (GAA) transistors) and the formation methods are provided. In accordance with some embodiments, gate dielectrics are formed on semiconductor nanostructures, which semiconductor nanostructures act as the channel regions of the of transistors. The gate dielectrics comprise interfacial layers and high-k dielectric layers over the interfacial layers. The thicknesses of the high-k dielectric layers of the portions of the high-k dielectric layers overlying, underlying, at corners, and on sidewalls of the nanosheets are modulated adopting different process conditions. By modulating the thicknesses of the gate oxides, the reliability and the performance of the nanostructure transistors may be tuned and balanced based on requirements.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

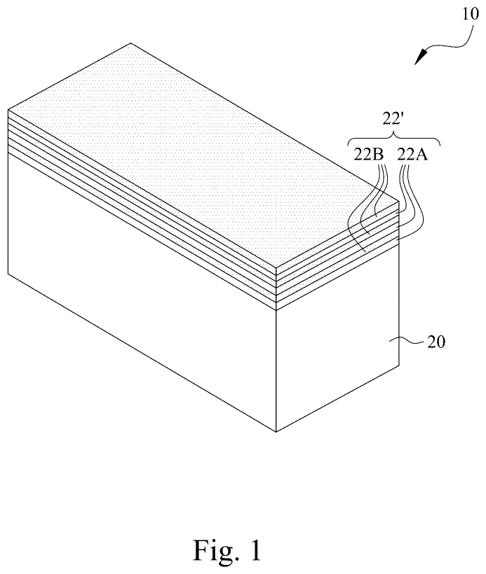

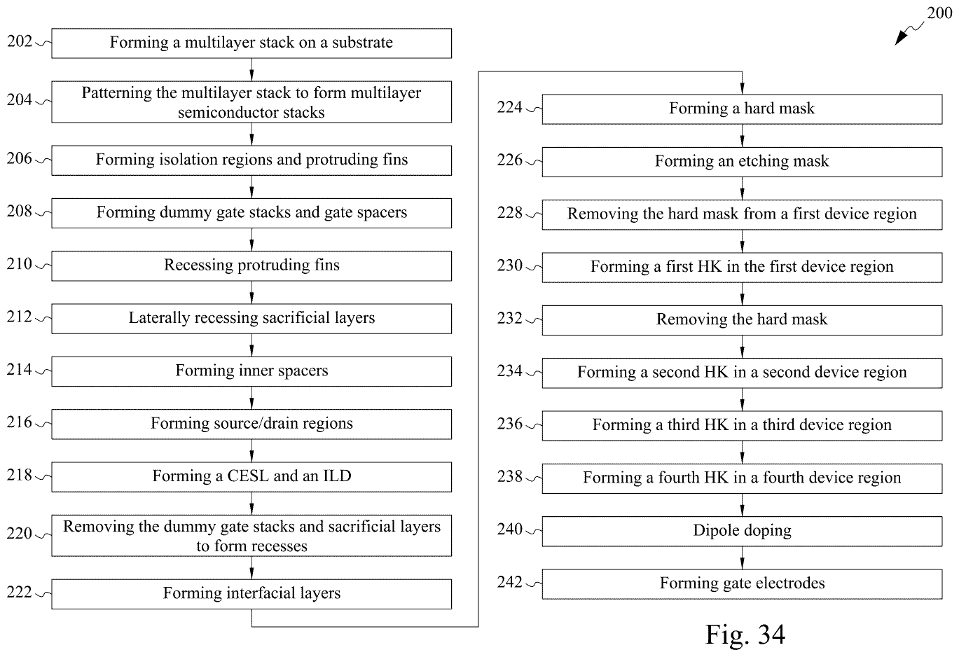

FIGS. 1-4, 5A, 5B, 6A, 6B, 7A, 7B, 8A, 8B, 9A, 9B, 10A, 10B, 11A, 11B, 12-28, 29A, 29B, 29C, 30A, and 30B illustrate the cross-sectional views of intermediate stages in the formation of a nanostructure transistor in accordance with some embodiments of the present disclosure. The corresponding processes are also reflected schematically in the process flow as shown in FIG. 34.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor substrate.

In accordance with some embodiments, multilayer stack 22 is formed through a series of deposition processes for depositing alternating materials. The respective process is illustrated as process 202 in the process flow 200 as shown in FIG. 34. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may include Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22A has thickness in the range between about 4 nm and 7 nm, while the second layer 22B has thickness in the range between about 8 nm and 12 nm, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

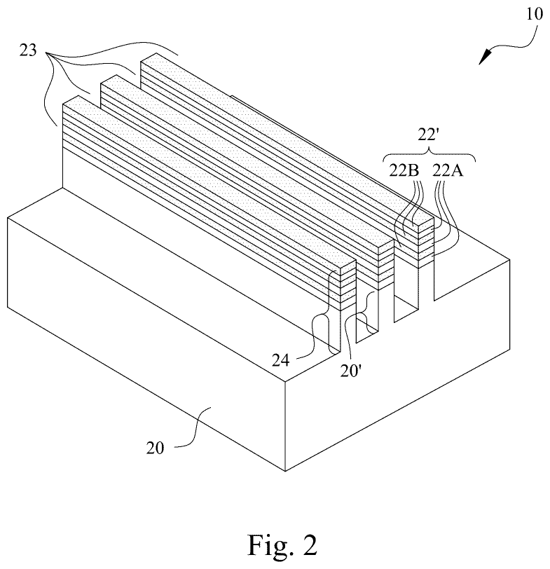

Referring to FIG. 2, multilayer stack 22 and a portion of the underlying substrate 20 are patterned in an etching process(es), so that trenches 23 are formed. The respective process is illustrated as process 204 in the process flow 200 as shown in FIG. 34. Trenches 23 extend into substrate 20. The remaining portions of multilayer stacks are referred to as multilayer stacks 22′ hereinafter. Underlying multilayer stacks 22', some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

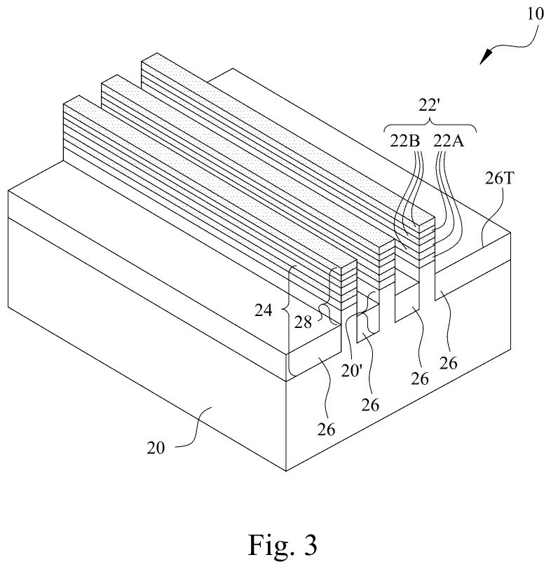

FIG. 3 illustrates the formation of isolation regions 26, which are also referred to as Shallow Trench Isolation (STI) regions throughout the description. The respective process is illustrated as process 206 in the process flow 200 as shown in FIG. 34. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

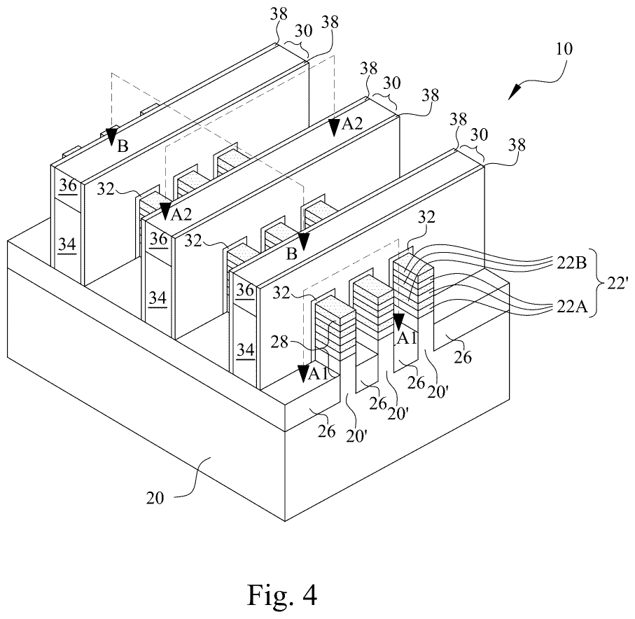

Referring to FIG. 4, dummy gate stacks 30 and gate spacers 38 are formed on the top surfaces and the sidewalls of (protruding) fins 28. The respective process is illustrated as process 208 in the process flow 200 as shown in FIG. 34. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

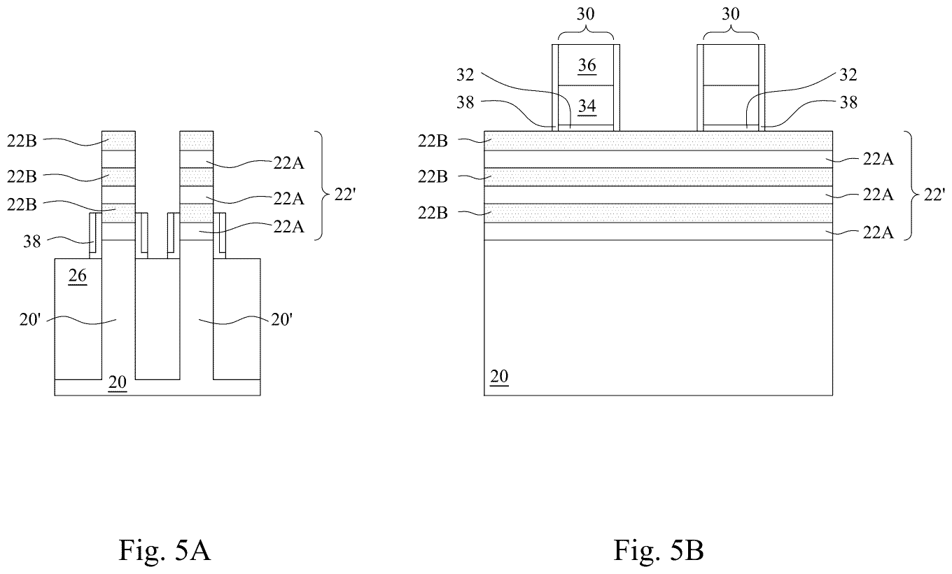

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by dummy gate stacks 30 and gate spacers 38, and is perpendicular to the gate-length direction. FIG. 5B illustrates the reference cross-section B-B in FIG. 4, which reference cross-section is parallel to the lengthwise directions of protruding fins 28.

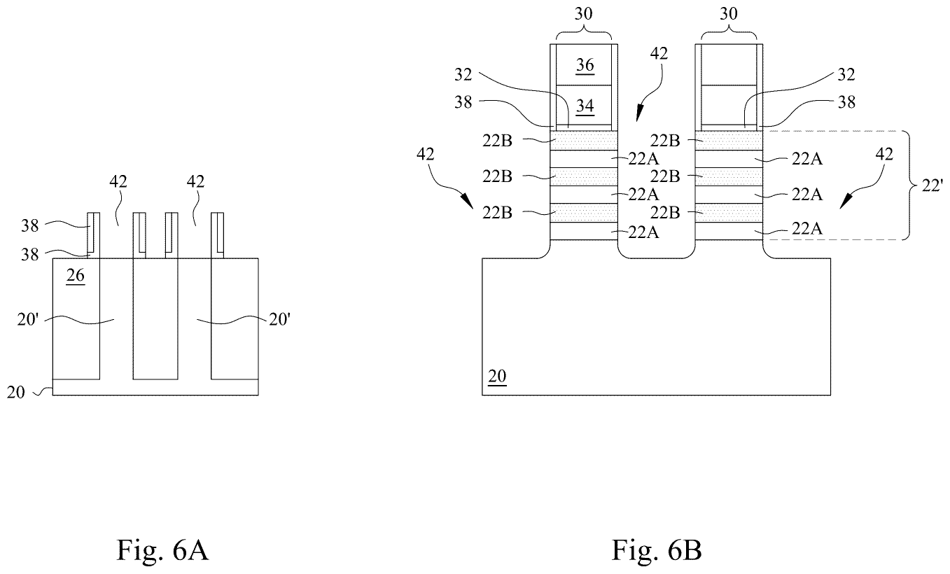

Referring to FIGS. 6A and 6B, the portions of protruding fins 28 (FIG. 4) that are not directly underlying dummy gate stacks 30 and gate spacers 38 are recessed through an etching process to form recesses 42. The respective process is illustrated as process 210 in the process flow 200 as shown in FIG. 34. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

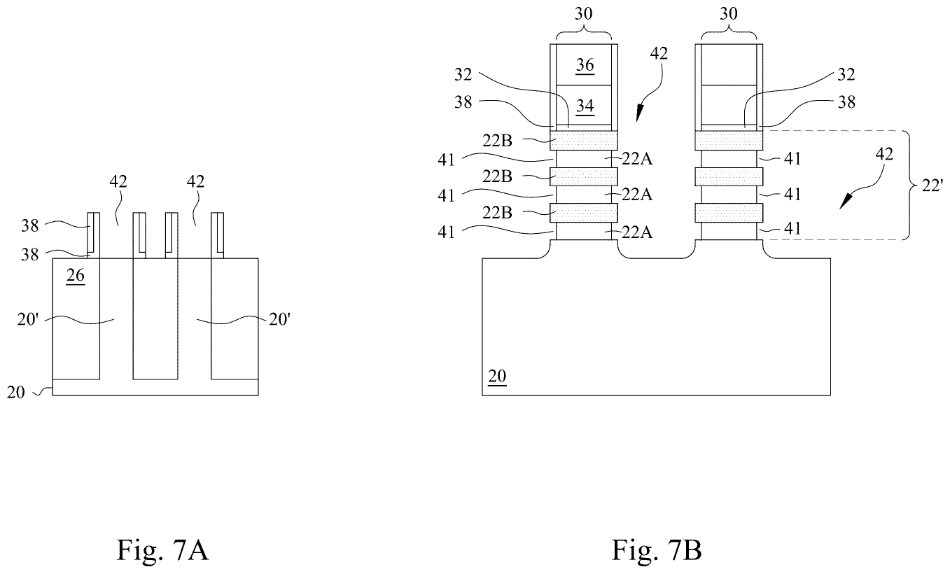

Referring to FIGS. 7A and 7B, sacrificial semiconductor layers 22A are laterally recessed to form lateral recesses 41, which are recessed from the edges of the respective overlying and underlying nanostructures 22B. The respective process is illustrated as process 212 in the process flow 200 as shown in FIG. 34.

The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, a spin-on process, or the like.

In accordance with alternative embodiments, the lateral recessing of sacrificial semiconductor layers 22A is performed through an isotropic dry etching process or a combination of a dry etching process and a wet etching process.

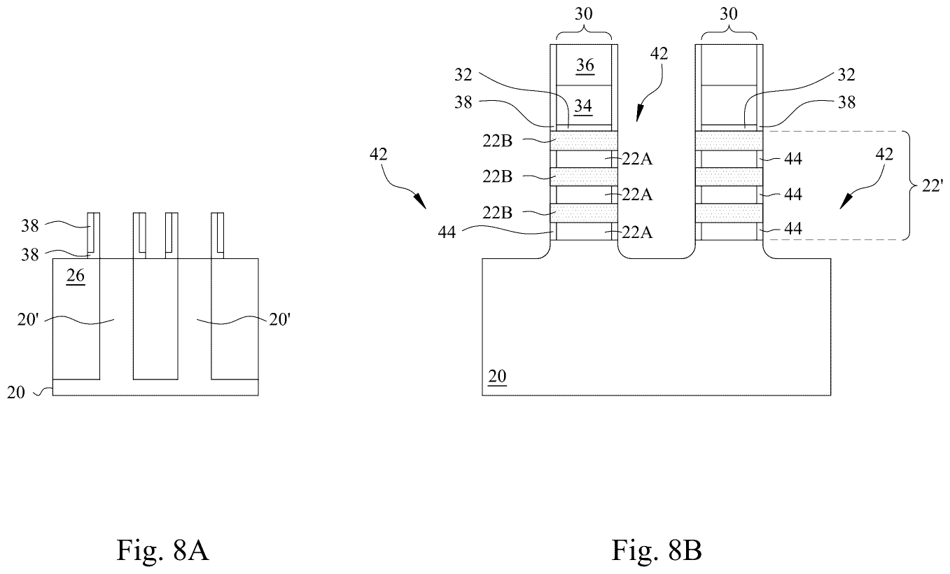

Referring to FIGS. 8A and 8B, inner spacers 44 are formed. The respective process is illustrated as process 214 in the process flow 200 as shown in FIG. 34. In accordance with some embodiments, the formation of inner spacers 44 includes depositing a conformal dielectric layer, which extends into the lateral recesses 41 (FIG. 7B). Next, an etching process (also referred to as a spacer trimming process) is performed to trim the portions of the spacer layer outside of the lateral recesses 41, leaving the portions of the spacer layer in the lateral recesses 41. The remaining portions of the spacer layer are referred to as inner spacers 44. Inner spacers 44 may be single-layer spacers, or may include a plurality of sub layers (such as two to three sub layers).

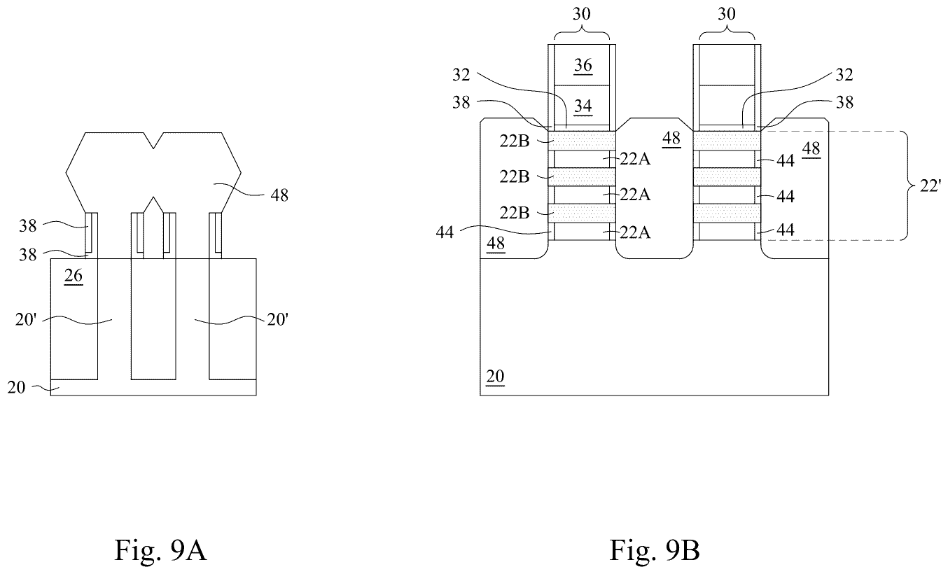

Referring to FIGS. 9A and 9B, epitaxial source/drain regions 48 are formed in recesses 42. The respective process is illustrated as process 216 in the process flow 200 as shown in FIG. 34. In accordance with some embodiments, the source/drain regions 48 may exert stress on the nanostructures 22B, which are used as the channels of the corresponding GAA transistors, thereby improving performance. Depending on whether the resulting transistor is a p-type transistor or an n-type transistor, a p-type or an n-type impurity may be in-situ doped with the proceeding of the epitaxy. For example, when the resulting transistor is a p-type Transistor, silicon germanium boron (SiGeB), silicon boron (SiB), or the like may be grown. Conversely, when the resulting transistor is an n-type Transistor, silicon phosphorous (SiP), silicon carbon phosphorous (SiCP), or the like may be grown. After recesses 42 are filled with epitaxy regions 48, the further epitaxial growth of epitaxy regions 48 causes epitaxy regions 48 to expand horizontally, and facets may be formed. The further growth of epitaxy regions 48 may also cause neighboring epitaxy regions 48 to merge with each other. Alternatively, at a time when the formation of epitaxy regions 48 is finished, the epitaxy regions 48 grown from different ones of substrate strips 20′ are separated from each other.

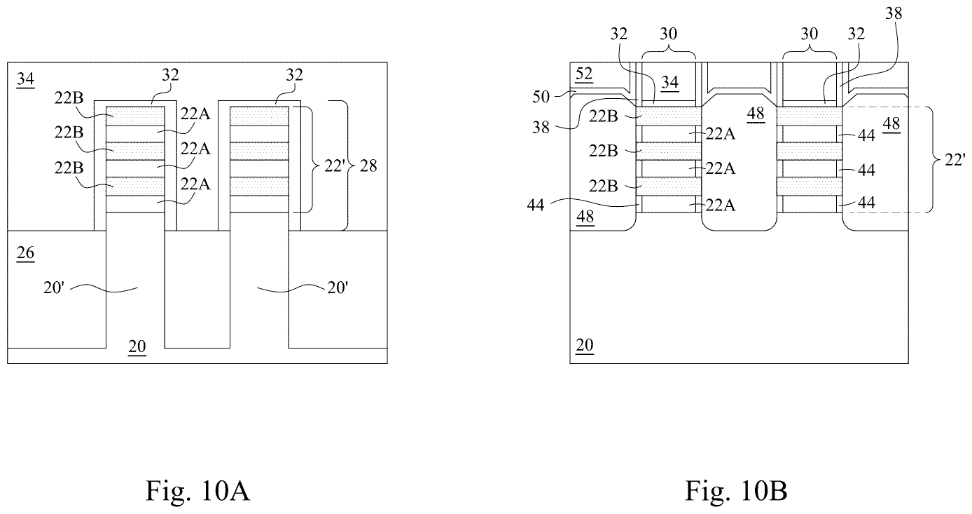

Referring to FIGS. 10A and 10B, Contact Etch Stop Layer (CESL) 50 and Inter-Layer Dielectric (ILD) 52 are formed. The respective process is illustrated as process 218 in the process flow 200 as shown in FIG. 34. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be silicon oxide, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. In accordance with some embodiments, the planarization process may remove hard masks 36 to reveal dummy gate electrodes 34, as shown in FIG. 10A. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

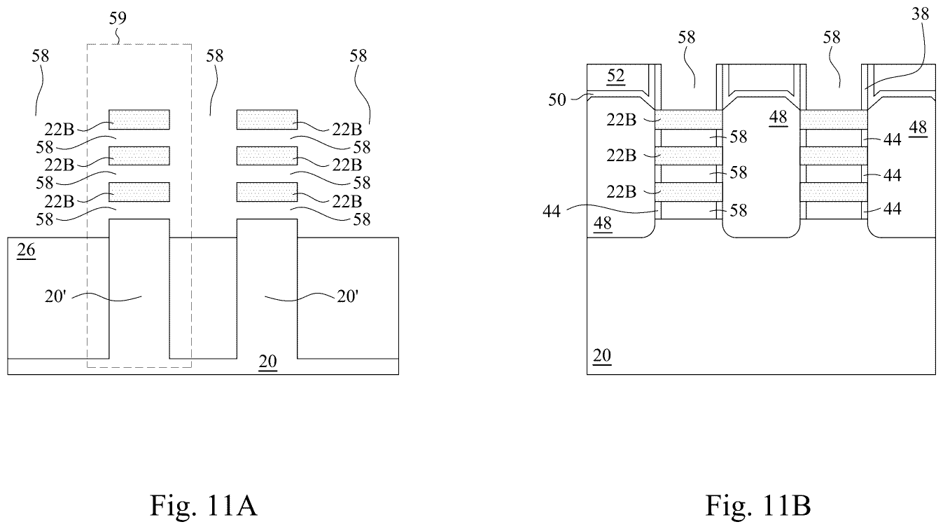

Next, dummy gate electrodes 34 and dummy gate dielectrics 32 (and hard masks 36, if remaining) are removed in one or more etching processes, so that recesses 58 are formed, as shown in FIGS. 11A and 11B. The respective process is illustrated as process 220 in the process flow 200 as shown in FIG. 34.

Sacrificial layers 22A are then removed to extend recesses 58 between nanostructures 22B. The respective process is also illustrated as process 220 in the process flow 200 as shown in FIG. 34. Sacrificial layers 22A may be removed by performing an isotropic etching process such as a wet etching process using etchants which are selective to the materials of sacrificial layers 22A, while nanostructures 22B, substrate 20, and STI regions 26 remain relatively un-etched as compared to sacrificial layers 22A.

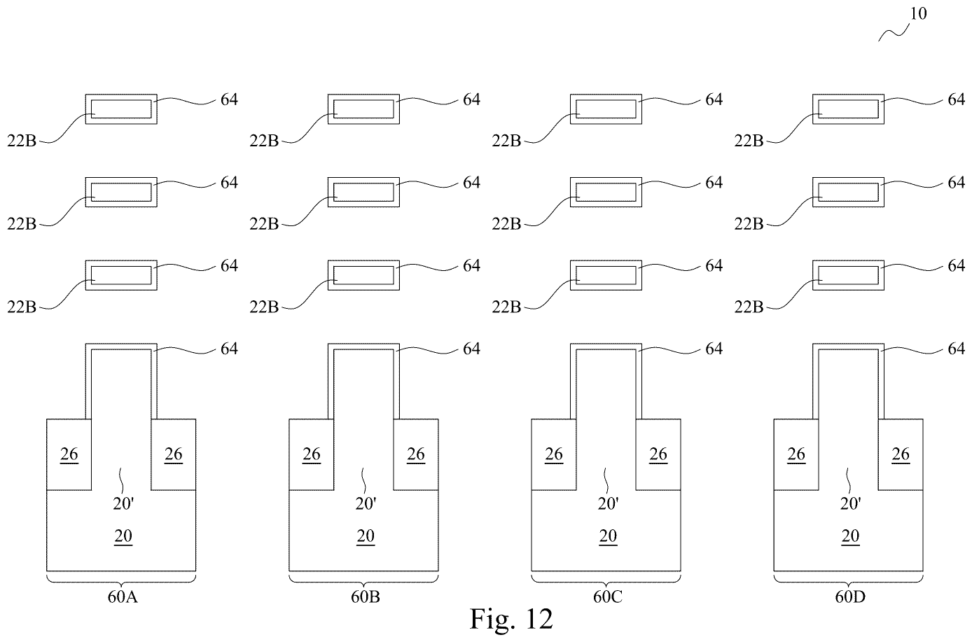

FIGS. 12 through 26 illustrate the views in the formation of gate dielectrics 68, which include interfacial layer 64 encircling nanostructures 22B, and high-k dielectric layers 66 over interfacial layer 64 in accordance with some embodiments. FIG. 12 illustrates portions of the wafer 10 in different device regions. The illustrated structures in different device regions are essentially the same as what are obtained from region 59 in FIG. 11A.

The preceding processes may be used for forming multiple nanostructure transistors that may meet different reliability requirements and different performance requirements. In subsequent discussion, four device regions are illustrated, each for forming a nanostructure transistor therein. For example, FIG. 12 illustrates device regions 60A, 60B, 60C, and 60D, and the structures shown therein are formed using the processes as discussed in preceding figures. Each of the device regions 60A, 60B, 60C, and 60D may be a p-type transistor region (in which a p-type transistor is to be formed) or an n-type transistor region (in which an n-type transistor is to be formed) in any combination.

Throughout the description, the portions of the gate dielectrics (and the corresponding high-k dielectric layers) overlying and on the top surfaces of nanostructures are referred to as the top (or upper) portions of gate dielectrics (and high-k dielectric layers). The portions of the gate dielectrics (and the corresponding high-k dielectric layers) underlying and contacting the bottom surfaces of nanostructures are referred to as the lower (or bottom) portions of gate dielectrics (and high-k dielectric layers). The top (or upper) portions of gate dielectrics over the topmost nanostructures 22B are referred to as the topmost portions of gate dielectrics. Similarly, the corner portions and sidewall portions of the gate dielectrics and high-k dielectric layers may be realized.

Device region 60A is a device region in which the high-k dielectric portion overlying the topmost nanostructure 22B is to be formed as thicker than other portions. Device region 60B is a device region in which the high-k dielectric portion overlying the topmost nanostructure 22B is to be formed as thinner than other portions. Device region 60C is a device region in which the thicknesses of the corner portions and sidewall portions are increased, with the sidewall portions to be formed as being thicker than the respective top portions and bottom portions. Device region 60D is a device region in which the inner portions (the top and bottom portions that face the overlying or underlying nanostructures 22B) are to be formed as thinner than the topmost portions, and may also be thinner than the sidewall portions.

As shown in FIG. 12, interfacial layers (ILs) 64 are formed, and may comprise silicon oxide. The respective process is illustrated as process 222 in the process flow 200 as shown in FIG. 34. The formation process may include an oxidation process. The oxidation process may be performed using oxygen, for example, by generating plasma from an oxygen-containing gas. The oxidation process may also comprise a chemical oxidation process. In accordance with some embodiments, the top portions, the bottom portions, and the sidewall portions of ILs 64 may have thicknesses equal to or close to each other, for example, with differences being smaller than about 20 percent or 10 percent.

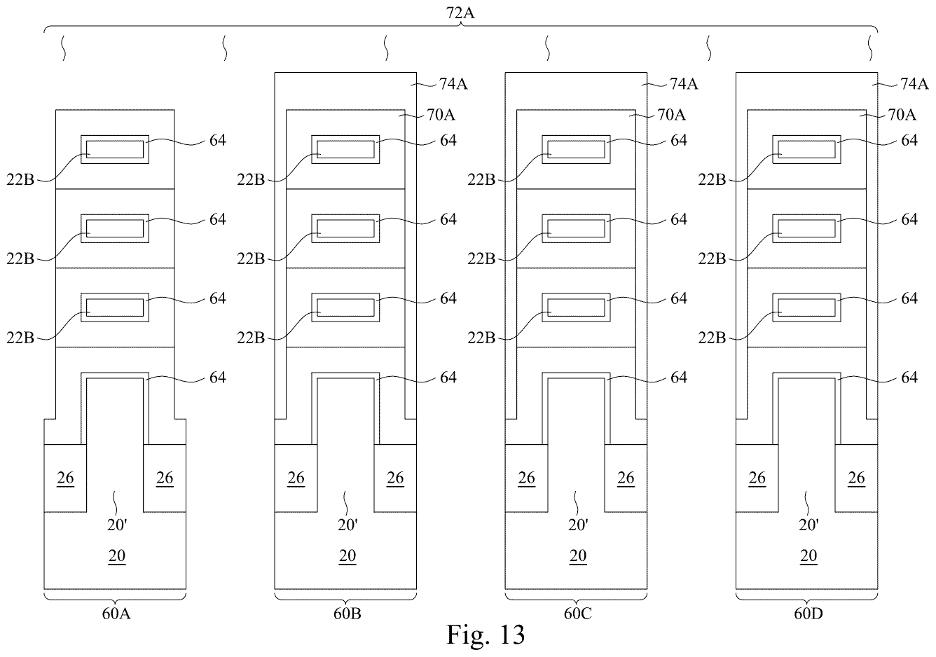

FIGS. 13-26 illustrate the formation of high-k dielectric layers 66A, 66B, 66C, and 66D in device regions 60A 60B, 60C, and 60D, respectively. High-k dielectric layers 66A, 66B, 66C, and 66D are individually and collectively referred to as high-k dielectric layers 66. In accordance with some embodiments, the high-k dielectric layers 66 may include a metal oxide or a silicate of hafnium, aluminum, zirconium, lanthanum, manganese, barium, titanium, lead, combinations thereof, and/or multi-layers thereof.

High-k dielectric layers 66 are deposited through deposition process such as ALD or CVD. These deposition processes are generally considered as conformal deposition processes. In accordance with some embodiments of the present disclosure, however, process conditional are tuned to change the thicknesses of some portions (top portions (top/upper horizontal portions), bottom portions (bottom/lower horizontal portions), sidewall portions (vertical portions), and corner portions) to be greater than or smaller than the thicknesses of other portions.

While high-k dielectric layers 66A, 66B, 66C, and 66D may be formed in different processes, the materials of high-k dielectric layers 66A, 66B, 66C, and 66D may be the same or different from each other in any combination. In the following discussion, the formation of HfO₂ is discussed as an example of the material of the high-k dielectric layers 66, while high-k dielectric layers 66 may also be formed of or comprise other types of high-k dielectric materials. The corresponding available precursors may also be realized.

FIGS. 13-16, FIGS. 17-19, FIGS. 20-22, and FIGS. 23-26 illustrate the formation of high-k dielectric layers 66 with different thickness profiles in accordance with various embodiments. Although the illustrated process flow illustrates that four different thickness profiles are formed in the same wafer and same device die, the nanostructure transistors formed in one wafer and device die may select a single thickness profile, two thickness profiles, or three thickness profiles (instead of all illustrated thickness profiles) in any combination, or four thickness profiles. Also, when more than one thickness profile is adopted, the sequence of forming different profiles may be any available sequence different from the illustrated sequence.

FIGS. 13-16 illustrate the processes for forming high-k dielectric layers 66A in device region 60A in accordance with some embodiments, wherein the topmost portion of high-k dielectric layers 66A over the topmost nanostructure 22B has a greater thickness than rest portions including the underlying bottom portions, top portions (that are under the topmost nanostructure 22B), and sidewall portions of the high-k dielectric layers 66A.

In accordance with some embodiments, the formation of the high-k dielectric layers 66A that comprise HfO₂ adopts tetrakis(ethylmethylamino)hafnium (TEMAH) as the hafnium precursor. H₂O, O₂, and/or O₃ may be used as the oxidant.

Referring to FIG. 13, hard mask 70A is formed. The respective process is illustrated as process 224 in the process flow 200 as shown in FIG. 34. Hard mask 70A may comprise a metal oxide, a metal nitride, a metal oxynitride, a metal nitricarbide, a metal oxynitricarbide, or the like. The metal in the hard mask 70A may include Al, Zr, Ti, La, or the like, or combinations thereof, while other metals may also be used. Non-metal containing materials may also be used to form hard mask 70A.

In accordance with some embodiments, hard mask 70A may be deposited through a conformal deposition process, such as ALD, CVD, or the like, so that the spacings between nanostructures 22B are filled. Hard mask 70A is deposited into device regions 60A, 60B, 60C, and 60D.

Etching mask 74A is then formed over the hard mask 70A in device regions 60A, 60B, 60C, and 60D. The respective process is illustrated as process 226 in the process flow 200 as shown in FIG. 34. Etching mask 74A may comprise a photoresist. Etching mask 74A is patterned and removed from device region 60A, and include portions remaining in device regions 60B, 60C, and 60D.

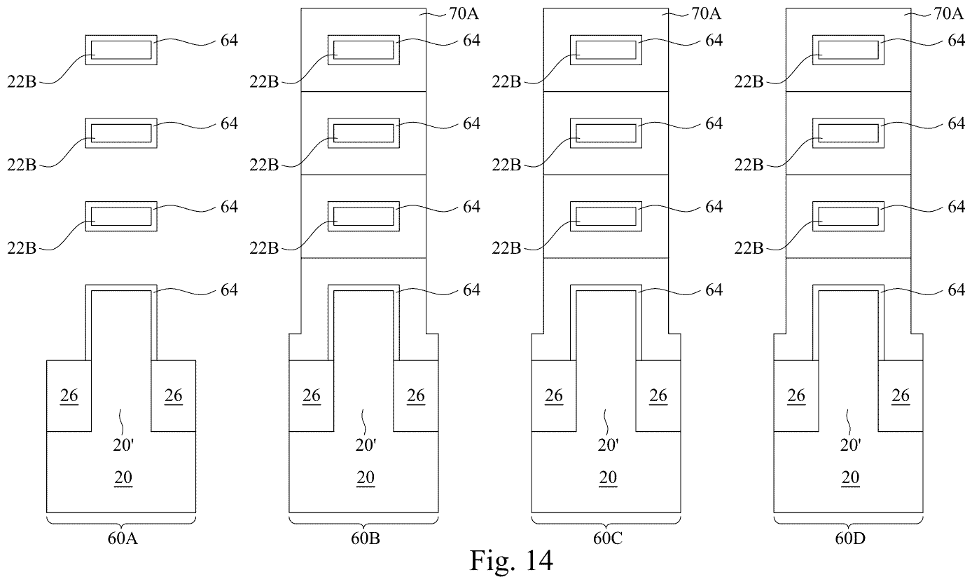

An etching process 72A is then performed to remove the portion of the hard mask 70A in device region 60A, so that the corresponding portions of ILs 64 are exposed. The respective process is illustrated as process 228 in the process flow 200 as shown in FIG. 34. After the etching process 72A, etching mask 74A is removed. The resulting structure is shown in FIG. 14.

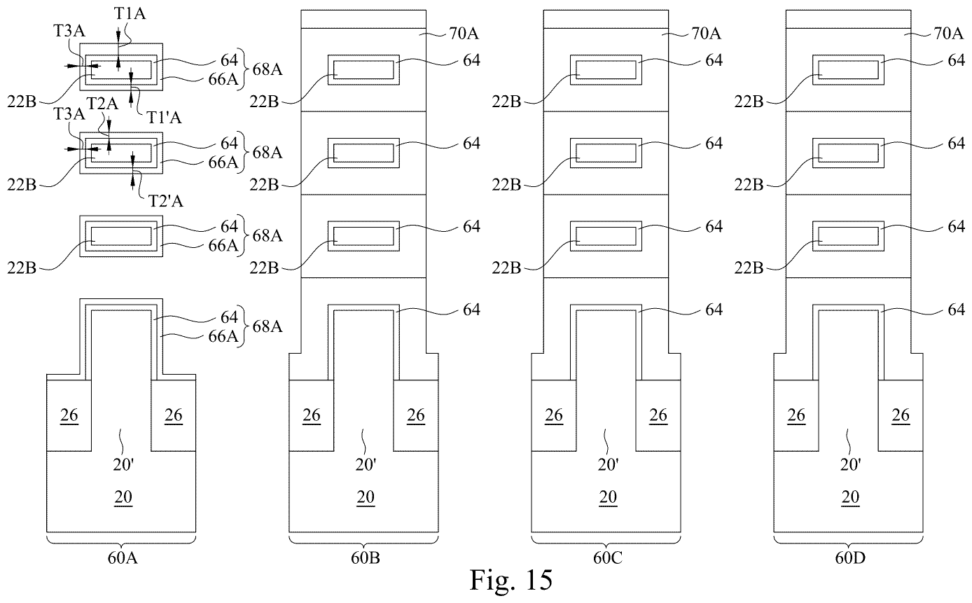

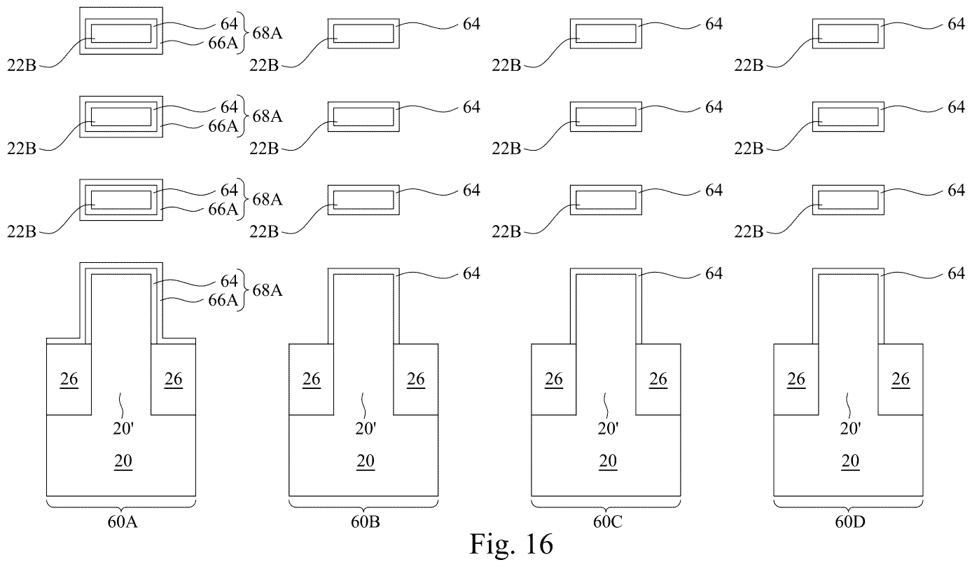

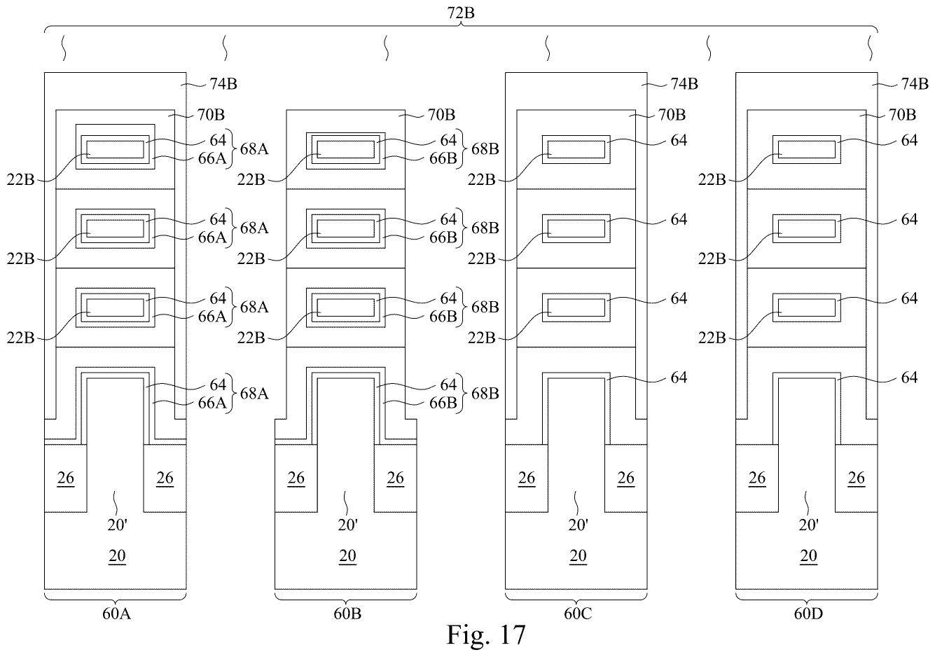

Referring to FIG. 15, high-k dielectric layers 66A are deposited. The respective process is illustrated as process 230 in the process flow 200 as shown in FIG. 34. In accordance with some embodiments, process conditions are adjusted, so that the thickness T1A of the topmost portion of the high-k dielectric layers 66A over the topmost nanostructure 22B is greater than the thicknesses T1′A and T2′A of the bottom portions and the thicknesses T3A of sidewall portions of high-k dielectric layers 66A. Thickness T1A is also greater than thicknesses T2A of the top portions of the high-k dielectric layers 66A that are underlying the topmost nanostructure 22B. For example, the thickness difference (T1A-T1′A) may be in the range between about 0.5 Å and about 2A. The ratio T1A/T1A′ is greater than 1.0, and may be in the range between about 1.1 and about 2.0. Alternatively stated, the thickness T1A is greater than thicknesses T1′A, T2A, T2′A and T3A. Thicknesses T1′A, T2A, T2′A, and T3A may be equal to or different from each other.

In accordance with some embodiments, high-k dielectric layers 66A are deposited through an ALD process. To increase the thickness T1A of the topmost portion of high-k dielectric layers 66A, the wafer temperature in the deposition process may be relatively high, for example, in the range between about 300° C. and about 400° C. The chamber pressure of the deposition chamber in which the ALD process is performed may also be relatively high, for example, in the range between about 3 Torr and about 4 Torr. The pulsing time for the hafnium precursor (assuming high-k dielectric layers 66A comprise hafnium oxide) (and possibly the oxidant) may be relatively long, for example, in the range between about 1 second and about 10 seconds. The purging time for the hafnium precursor (and possibly the oxidant) may also be relatively long, for example, in the range between about 1 second and about 5 seconds. Longer pulsing time may result in greater thicknesses of the high-k dielectric layers, and longer purging time may result in smaller thicknesses of the high-k dielectric layers, and vice versa.

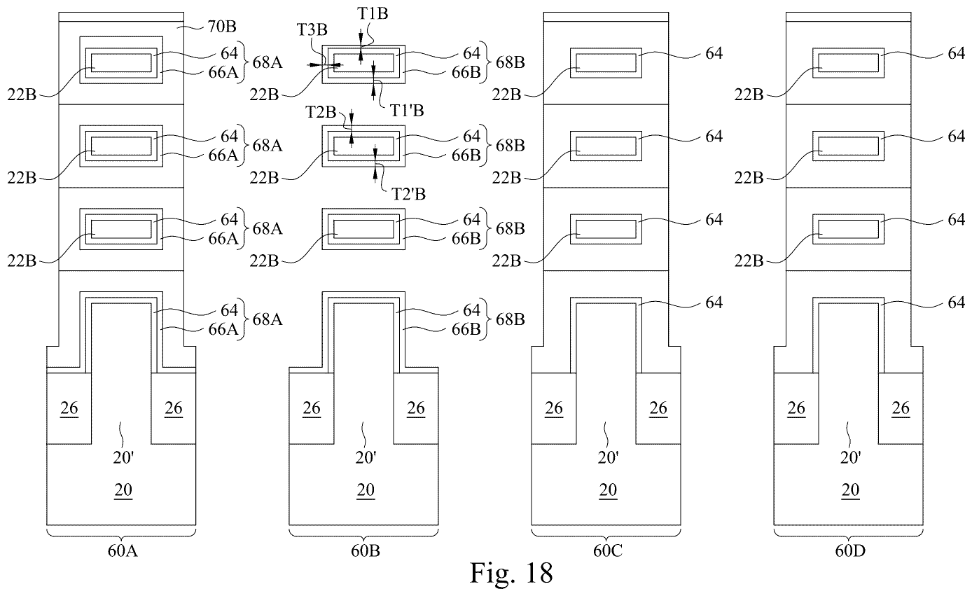

Throughout the description, when a first process condition is described as being relatively high/long, and a second process condition is described as being relatively low/short, it may also mean that the first process condition is higher (or longer) than the second process condition. For example, when the first wafer temperature for forming high-k dielectric layers 66A is relatively high, and the second wafer temperature for forming high-k dielectric layers 66B (FIG. 18) is relatively low, it may also mean that the first wafer temperature is higher than the second wafer temperature. Similarly, when the first pulsing time (or purging time) for forming high-k dielectric layers 66A is relatively long, and the second pulsing time (or purging time) for forming high-k dielectric layers 66B (FIG. 18) is relatively short, it may also mean that the first pulsing time (or purging time) is longer than the second pulsing time (or purging time).

Hard mask 70A is then removed through an etching process, and the resulting structure is shown in FIG. 16. The respective process is illustrated as process 232 in the process flow 200 as shown in FIG. 34. The removal of the hard mask 70A may include forming a patterned etching mask (not shown) to cover device region 60A while leaving device regions 60B, 60C, and 60D open, etching the portions of high-k dielectric layers 66A that are over the portions of hard mask 70A, etching hard mask 70A, and removing the patterned etching mask.

It is advantageous to make the topmost portions of the high-k dielectric layers 66A to be thicker in some situations. For example, increasing the topmost portions of high-k dielectric layers 66A may improve the yield and reliability. These embodiments may be adopted when a subsequent dipole incorporation process is adopted, which may include etching/cleaning processes that may cause yield and reliability problems.

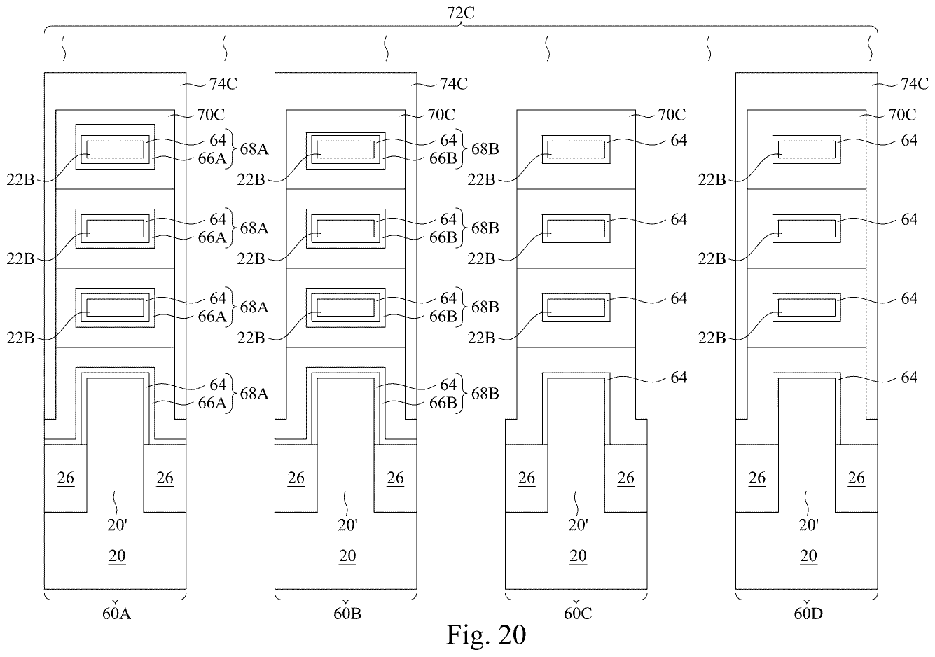

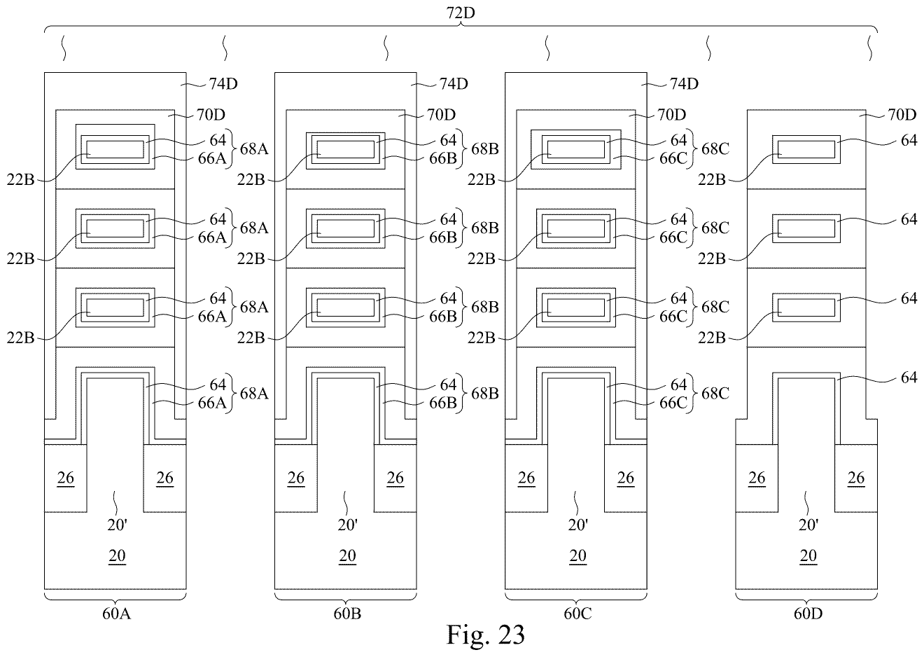

FIGS. 17-19 illustrate the formation of high-k dielectric layers 66B in device region 60B. The respective process is illustrated as process 234 in the process flow 200 as shown in FIG. 34. Also, FIGS. 20-22 illustrate the formation of high-k dielectric layers 66C in device region 60C, and FIGS. 23-26 illustrate the formation of high-k dielectric layers 66D in device region 60D. Unless specified otherwise, the materials, the structures, and the formation processes of the components in these processes are essentially the same as the like components denoted by like reference numerals in the processes as discussed referring to FIGS. 12-16. The details regarding the materials, the structures, and the formation processes provided regarding one device region throughout the description may be applied to other device regions whenever applicable.

Referring to FIG. 17, hard mask 70B is deposited and patterned, and etching mask 74B is formed. The portion of etching mask 74B in device region 60B is removed, and the portions in device regions 60A, 60C, and 60D remain. Next, etching process 72B is performed to remove the hard mask 70B in device region 60B. Etching mask 74B is then removed, and the resulting structure is shown in FIG. 18.

FIG. 18 also illustrates the deposition of high-k dielectric layers 66B in accordance with some embodiments. Process conditions are adjusted, so that the thickness T1B of the topmost portion of the high-k dielectric layers 66B over the topmost nanostructure 22B is smaller than the thicknesses T1′B and T2′B of the bottom portions and the thicknesses T3B of the sidewall portions of high-k dielectric layers 66B. Thickness T1B is also smaller than thicknesses T2B of the top portions of the high-k dielectric layers 66B that are underlying the topmost nanostructure 22B. For example, the thickness difference (T1′B-T1B) may be in the range between about 0 Å and about 0.5 Å. The ratio T1′B/T1B may be in the range between about 1.1 and about 2. Alternatively stated, the thickness T1B is reduced to be smaller than thicknesses T1′, T1′B, T2B, T2′B, and T3B. Thicknesses T1′B, T2B, T2′B, and T3B may be equal to or different from each other.

In accordance with some embodiments, there may also exist the relationship T1B<T1A (FIG. 15) and T1′B=>T1′A.

In accordance with some embodiments, to reduce thickness T1B, the wafer temperature may be relatively low, for example, in the range between about 200° C. and about 300° C. The chamber pressure of the deposition chamber in which the ALD process is performed is relatively low, for example, in the range between about 1 Torr and about 3 Torr. The pulsing time for the hafnium precursor (assuming high-k dielectric layers 66B comprise hafnium oxide) and possibly the oxidant may be relatively short, for example, in the range between about 0.1 second and about 3 seconds. The purging time for the precursor and possibly the oxidant may be relatively short, for example, in the range between about 0.1 second and about 2 seconds.

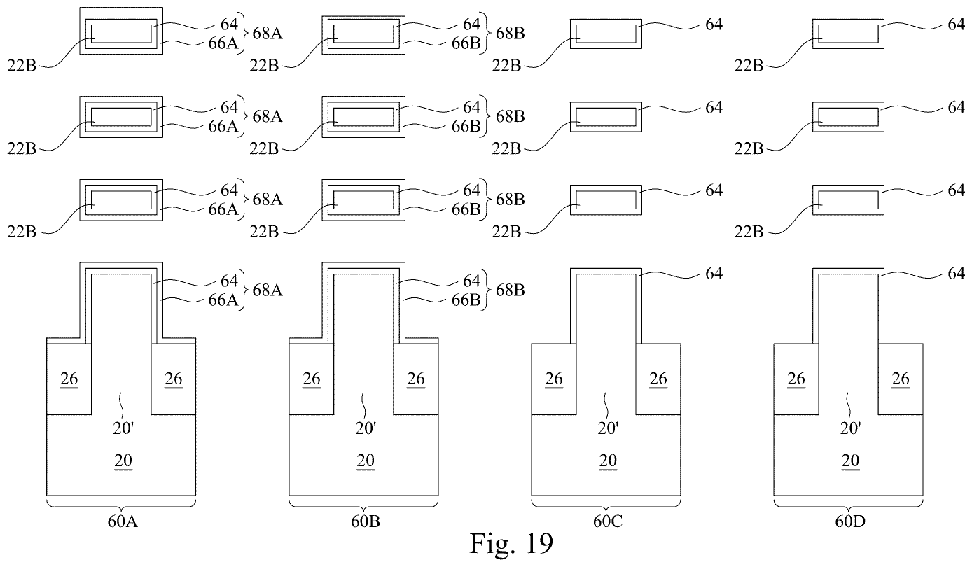

Hard mask 70B is then removed through an etching process, and the resulting structure is shown in FIG. 19. The removal of the hard mask 70B may include forming a patterned etching mask (not shown) to cover device region 60B while leaving device regions 60A, 60C, and 60D open, etching the portions of high-k dielectric layers 66B that are over the portions of hard mask 70B, etching hard mask 70B, and removing the etching mask.

It is advantageous to make the top portions of the high-k dielectric layers 66B to be thinner in some situations. These embodiments may be adopted when dipole incorporation process is not adopted, and there is no concern of yield and reliability problems.

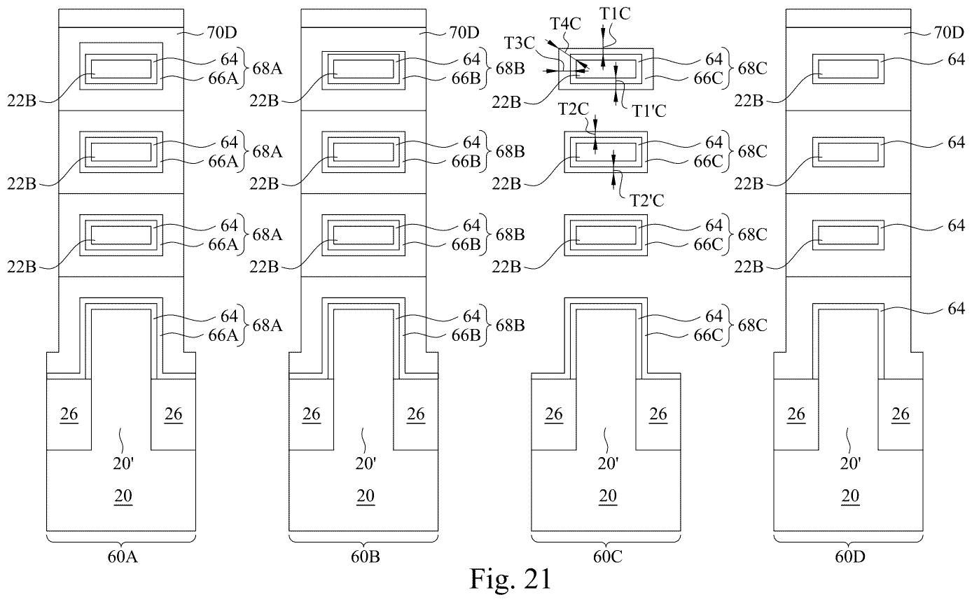

FIGS. 20-22 illustrate the formation of high-k dielectric layers 66C in accordance with some embodiments. The respective process is illustrated as process 236 in the process flow 200 as shown in FIG. 34. Referring to FIG. 20, hard mask 70C is deposited and patterned, and etching mask 74C is formed. The portion of etching mask 74C in device region 60C is removed, and the portions in device regions 60A, 60B, and 60D remain. Next, etching process 72C is performed to remove the hard mask 70C in device region 60C. Etching mask 74C is then removed, and the resulting structure is shown in FIG. 21.

FIG. 21 also illustrates the deposition of high-k dielectric layers 66C in accordance with some embodiments. Process conditions are adjusted, so that the thickness T3C of the sidewall portions of the high-k dielectric layers 66C is greater than the thicknesses T1C, T1′C, T2C, and T2′C. For example, the thickness differences (T3C-T1C), (T3C-T1′C), (T3C-T2C), and (T3C-T2C) may be greater than about 0.5 A, and may be in the range between about 0.5 Å and about 2 Å. The thickness ratios T3C/T1C, T3C/T1′C, T3C/T2C, and T3C/T2′C may be greater than about 1.1, and may be in the range between about 1.1 and about 2.0.

In accordance with some embodiments, there may also exist the relationship T3C>T3A (FIG. 15), T3C>T3B (FIG. 18), T1C<T1A (FIG. 15), and T1C>T1B (FIG. 18).

In accordance with some embodiments, to increase sidewall thickness T3C and corner thickness T4C, the wafer temperature may be relatively high, for example, in the range between about 300° C. and about 400° C. The chamber pressure of the deposition chamber in which the ALD process is performed is relatively high, for example, in the range between about 3 Torr and about 4 Torr. The pulsing time for the hafnium precursor (assuming high-k dielectric layers 66C comprise hafnium oxide) and possibly the oxidant may be relatively long, for example, in the range between about 1 second and about 10 seconds. The purging time for the hafnium precursor and possibly the oxidant may be relatively long, for example, in the range between about 1 second and about 5 seconds.

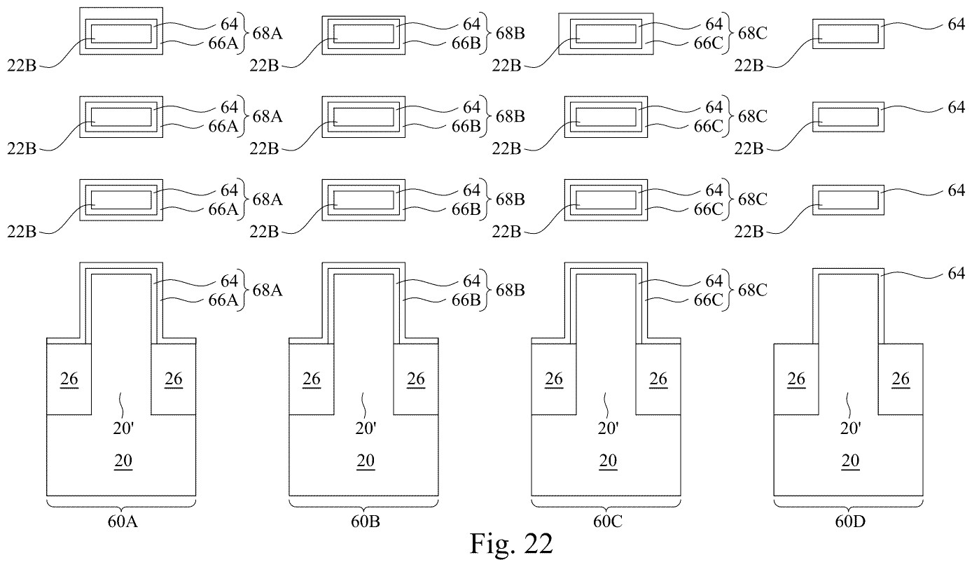

Hard mask 70C is then removed through an etching process, and the resulting structure is shown in FIG. 22.

It is advantageous to make the sidewall portions and corner portions of the high-k dielectric layers 66C to be thicker in some situations. For example, increasing the sidewall portions and corner portions of high-k dielectric layers may improve the yield and reliability. These embodiments may be adopted when a dipole incorporation process is to be performed, and the corresponding etching/cleaning process may cause yield and reliability problems.

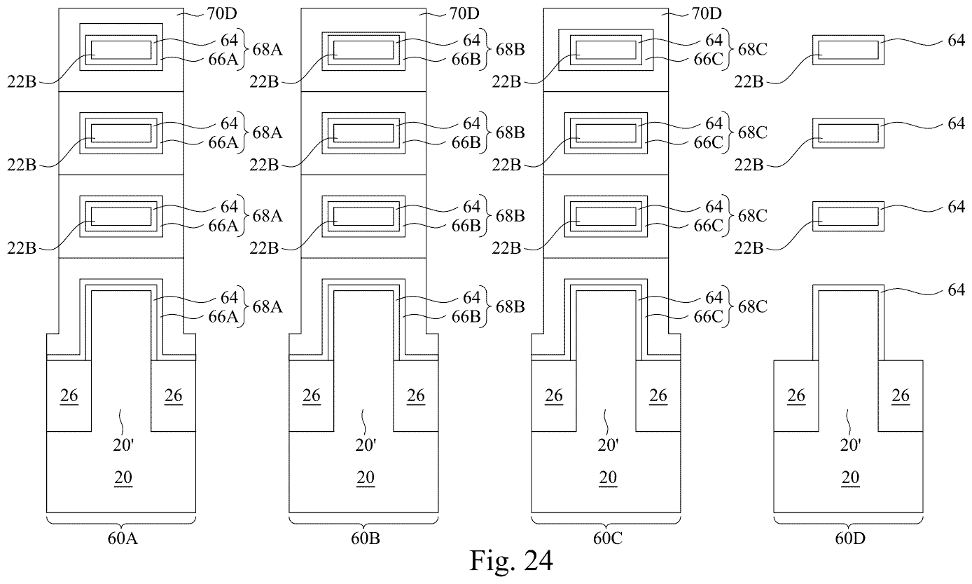

FIGS. 23-26 illustrate the formation of high-k dielectric layers 66D in accordance with some embodiments. The respective process is illustrated as process 238 in the process flow 200 as shown in FIG. 34. Referring to FIG. 23, hard mask 70D is deposited and patterned, and etching mask 74D is formed. The portion of etching mask 74D in device region 60D is removed, and the portions in device regions 60A, 60B, and 60C remain. Next, etching process 72D is performed to remove the hard mask 70D in device region 60D. Etching mask 74D is then removed, and the resulting structure is shown in FIG. 24.

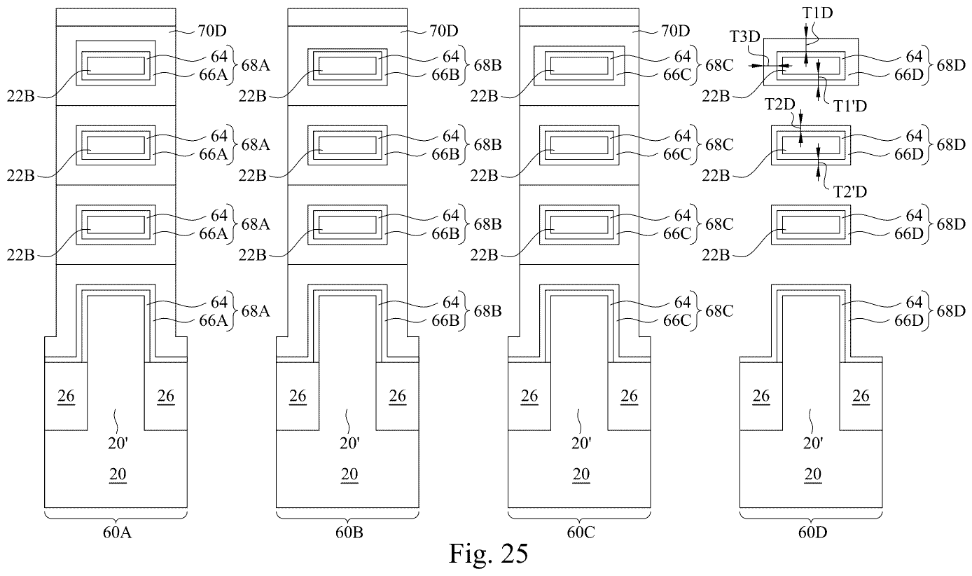

FIG. 25 illustrates the deposition of high-k dielectric layers 66D in accordance with some embodiments. Process conditions are adjusted, so that the inner thicknesses T1′D, T2D, and T2′D of the inner portions of high-k dielectric layers 66C are reduced to be smaller than thickness T1D and T3D. Throughout the description, the portions of high-k dielectric layers facing the overlying or underlying nanostructures 22B are referring to the inner portions, and their thicknesses T1′D, T2D, and T2′D are referred to as inner thicknesses. Thicknesses T1D and T3D may be greater than the inner thicknesses T1′D, T2D, and T2′D by thickness differences that are greater than about 0.5 Å, and may be in the range between about 0.5 Å and about 1 Å. The thickness ratios (T1D or T3D)/(T1′D or T2D or T2′D) may be greater than about 1.1, and may be in the range between about 1.1 and about 2.0. The inner thicknesses T1′D, T2D, and T2′D may be smaller than about 1.5 Å.

In accordance with some embodiments, there may also exist the relationship T1′D<T1′A (FIG. 15), T1D<T1A (FIG. 15) and T3D=T3A (FIG. 15), T1′D<T1′B (FIG. 18), T1D>T1B (FIG. 18), T3D=T3A (FIG. 18), and T1′D<T1′C (FIG. 21), and T1D=T1C (FIG. 21).

In accordance with some embodiments, to reduce the inner thicknesses T1′D, T2D, and T2′D, the wafer temperature may be relatively high, for example, in the range between about 300° C. and about 400° C. The chamber pressure of the deposition chamber in which the ALD process is performed is relatively high, for example, in the range between about 3 Torr and about 4 Torr. The pulsing time for the precursor (assuming high-k dielectric layers 66B comprise hafnium oxide) and possibly the oxidant may be relatively short, for example, in the range between about 0.1 second and about 3 seconds. The purging time for the precursor may be relatively short, for example, in the range between about 0.1 second and about 0.2 seconds.

It is advantageous to make the inner portions of the high-k dielectric layers 66D to be thinner in some situations. For example, reducing the inner thicknesses of high-k dielectric layers may improve the device performance (such as currents). Also, reducing the inner thicknesses of high-k dielectric layers makes the filling of dipole films (not shown) easier in subsequent processes, so that the dipole films may fill all of the spaces between the nanostructures 22B.

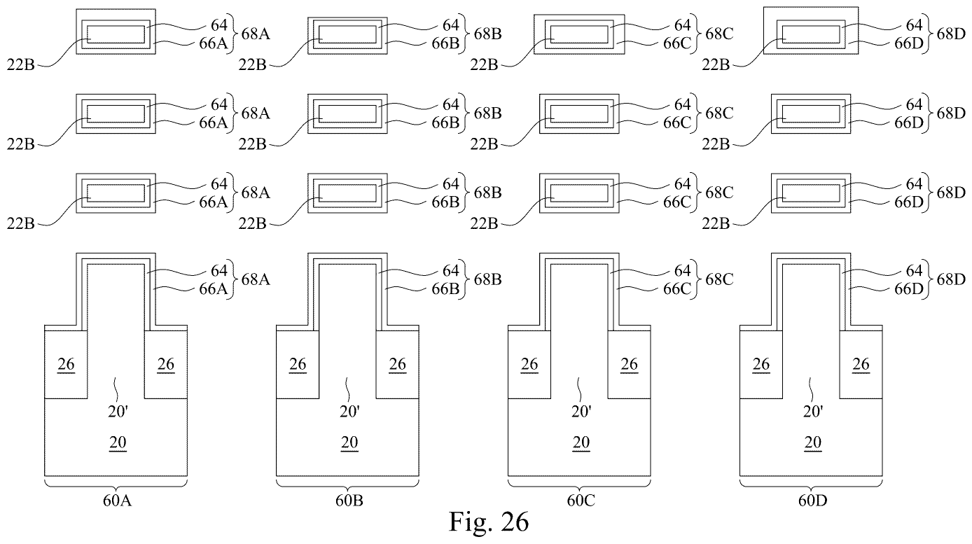

Hard mask 70D is then removed through an etching process, and the resulting structure is shown in FIG. 26. In FIG. 26, the ILs 64 and the respective overlying high-k dielectric layers 66A, 66B, 66C, and 66D collectively form gate dielectrics 68A, 68B, 68C, and 68D, respectively.

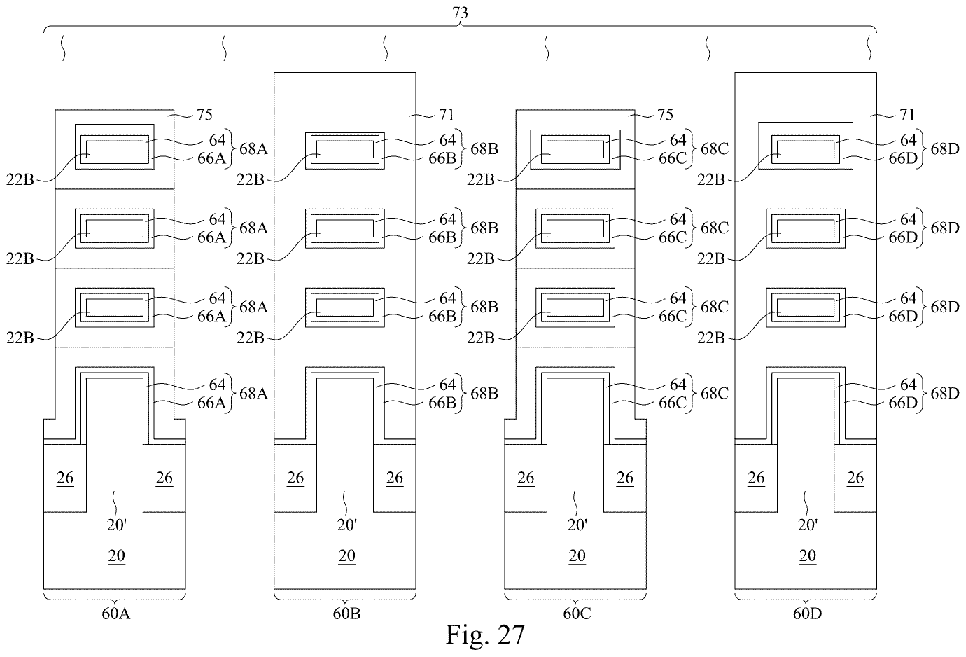

FIG. 27 illustrates an embodiment in which dipole films 75 are formed for doping dipole dopants into high-k dielectric layers 66A and 66C, so that the threshold of the respective nanostructure transistors in device regions 66A and 66C are tuned. In other embodiments, the dipole doping process is skipped. The dipole films 75 may comprise n-type dipole dopants, which may reduce the threshold voltage of n-type nanostructure transistors and increase the threshold voltage of p-type nanostructure transistors. Alternatively, the dipole films 75 may comprise p-type dipole dopants, which may increase the threshold voltage of n-type nanostructure transistors and reduce the threshold voltage of p-type nanostructure transistors.

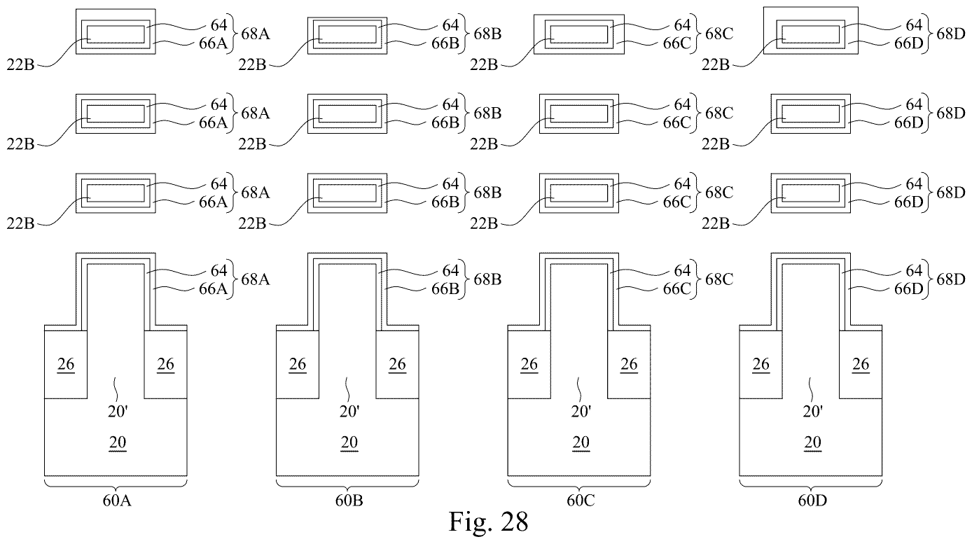

FIG. 27 further illustrates the annealing process 73 for driving/incorporating the dipole dopant in dipole films 75 into high-k dielectric layers 66A and 66C. The respective process is illustrated as process 240 in the process flow 200 as shown in FIG. 34. In accordance with alternative embodiments, the dipole doping process is skipped. After the annealing process, dipole films 75 are removed. FIG. 28 illustrates the resulting structure. With the top portions or sidewall/corner portions being thicker, high-k dielectric layers 66A and 66C are less likely to be damaged in the etching of dipole films 75.

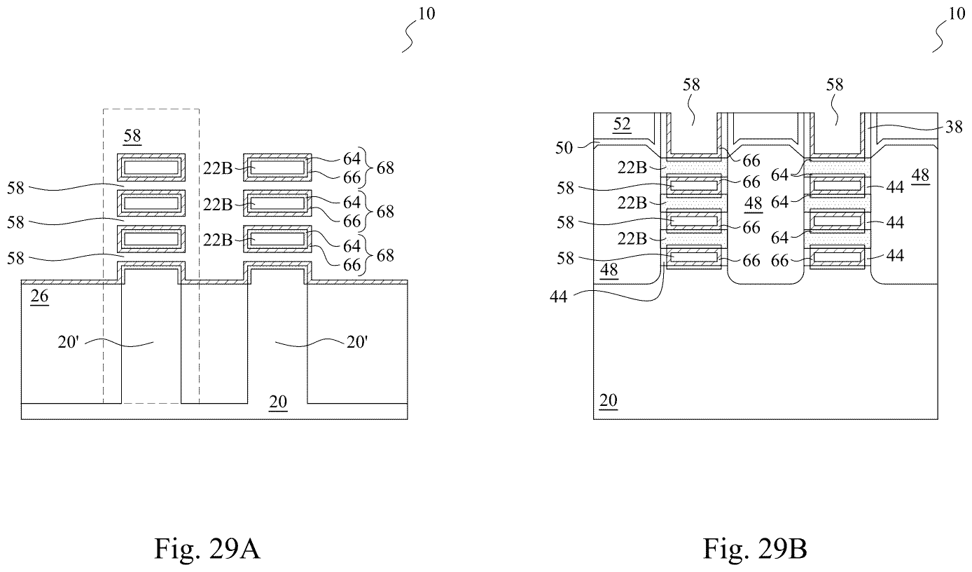

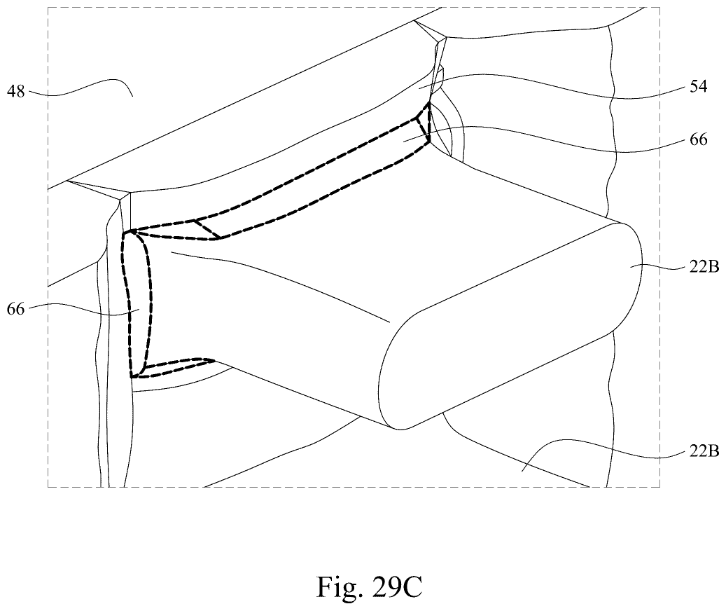

FIGS. 29A and 29B illustrate the cross-sections of wafer 10 after the formation of ILs 64 and high-k dielectric layers 66, as discussed in preceding embodiments. The illustrate gate dielectrics 68 represent the gate dielectrics 68A, 68B, 68C, and 68D as shown in FIG. 28.

FIG. 29C illustrate a perspective view of a portion of nanostructures 22B and the corresponding high-k dielectric 66. It is appreciated some features are not shown. It may be found from FIG. 29C that thicker gate dielectrics 68 (due to thicker high-k dielectric layers 66) are desirable for improving yield and reliability, and not desirable for improving device performance. Conversely, thinner gate dielectrics 68 are desirable for improving device performance, and are not desirable for improving yield and reliability. Accordingly, the embodiments of the present disclosure may be used to suit to different requirements.

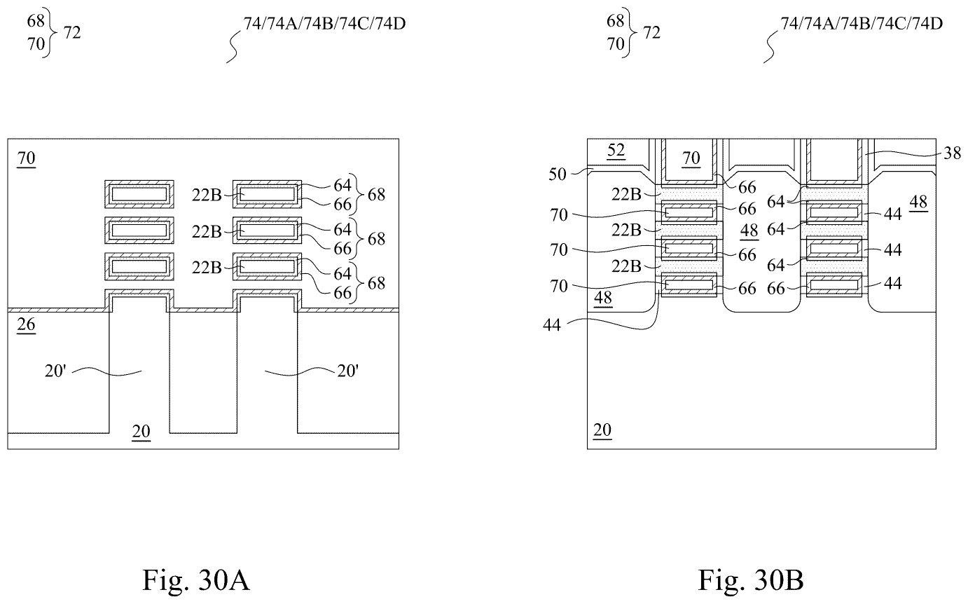

Gate electrodes 70 are then formed, as shown in FIGS. 30A and 30B. The respective process is illustrated as process 242 in the process flow 200 as shown in FIG. 34. Gate dielectrics 68 and gate electrodes 70 collectively form replacement gate stacks 72. In the formation process of gate electrodes 70, conductive layers are first formed over the high-k dielectric layers 66, so that the remaining portions of recesses 58 are filled, followed by a planarization process such as a CMP process or a mechanical grinding process to remove excess materials. Gate electrodes 70 may include a metal-containing material such as TiN, TaN, TiAl, TiAlC, cobalt, ruthenium, aluminum, tungsten, combinations thereof, and/or multilayers thereof. Nanostructure transistor 74 is thus formed, and may represent nanostructure transistors 74A, 74B, 74C, and 74D, which have the gate dielectrics 68A, 68B, 68C, and 68D as shown in FIG. 28.

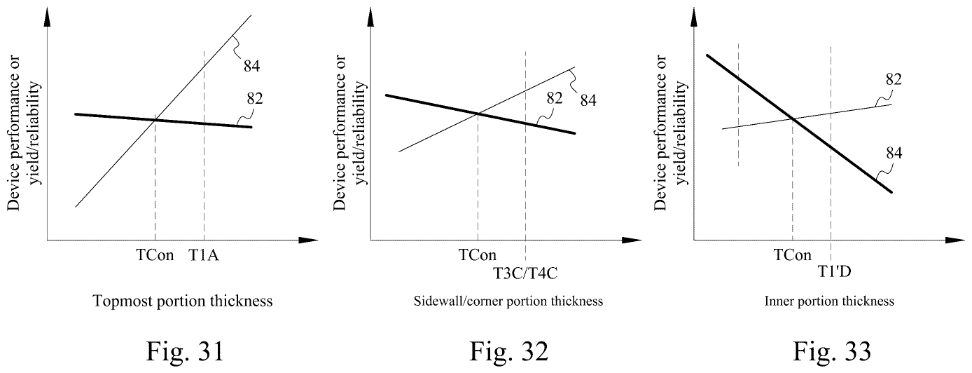

FIGS. 31-33 schematically illustrate the effects of adjusting the thicknesses of different parts of the high-k dielectric layers to adjust the device performance and yield and reliability (referred to as yield/reliability). The X-axes represent thickness, and the Y-axes represent either device performance or yield/reliability. Line 82 represents device performance, and illustrates that with the increase in the thickness of high-k dielectric layers, the device performance drops. Line 84 represents yield/reliability, and illustrates that with the increase in the thickness of high-k dielectric layers, the yield/reliability improves.

The X-axis in FIG. 31 illustrates the thickness of the topmost portion of high-k dielectric layers 66A (FIG. 15). The yield/reliability and device performance of nanostructure transistors with conformal high-k dielectric layers would be at the position with thickness equal to TCon, and the yield/reliability and device performance of nanostructure transistor 74A (FIGS. 30A and 30B) with the topmost portion of high-k dielectric layers 66A being thicker would be at the position with thickness equal to T1A (FIG. 15). It is appreciated that the nanostructure transistor 74A has reduced device performance, and improved yield/reliability.

The X-axis in FIG. 32 illustrates the thicknesses of the corner/sidewall portions of high-k dielectric layers 66C (FIG. 21). The yield/reliability and device performance of nanostructure transistors with conformal high-k dielectric layers would be at the position with thickness equal to TCon, and the yield/reliability and device performance of nanostructure transistor 74C (FIGS. 30A and 30B) with the thicker corner/sidewall portions of high-k dielectric layers 66C would be at the position with thickness equal to T3C/T4C (FIG. 21). It is appreciated that the transistor nanostructure transistor 74D has reduced device performance, and improved yield/reliability.

The X-axis in FIG. 33 illustrates the thicknesses of the inner portions of high-k dielectric layers 66D (FIG. 25). The yield/reliability and device performance of nanostructure transistors with conformal high-k dielectric layers would be at the position with thickness equal to TCon, and the yield/reliability and device performance of nanostructure transistor 74D (FIGS. 30A and 30B) with the thinner inner portions of high-k dielectric layers 66D would be at the position with the inner thickness equal to (FIG. 25) T1′D. It is appreciated that the nanostructure transistor 74C has improved device performance, and reduced yield/reliability.

The embodiments of the present disclosure have some advantageous features. By adopting different process conditions to modulate the profiles for high-k dielectric layers, nanostructure transistors may be modulated for different requirements such as improved yield and reliability, or improved device performance.

In accordance with some embodiments of the present disclosure, a method comprises forming a first plurality of semiconductor nanostructures comprising a first lower semiconductor nanostructure; and a first topmost semiconductor nanostructure over the first lower semiconductor nanostructure; forming interfacial layers contacting the first plurality of semiconductor nanostructures; and depositing first high-k dielectric layers encircling the interfacial layers, wherein a first topmost high-k dielectric layer of the first high-k dielectric layers encircling the first topmost semiconductor nanostructure comprises a first topmost horizontal portion overlapping the first topmost semiconductor nanostructure; a first bottom horizontal portion overlapped by the first topmost semiconductor nanostructure; and a first sidewall portion on a sidewall of the first topmost semiconductor nanostructure, wherein a first portion selected from the first topmost horizontal portion, the first bottom horizontal portion, and the first sidewall portion has a first thickness, and a second portion selected from the first topmost horizontal portion, the first bottom horizontal portion, and the first sidewall portion has a second thickness different from the first thickness.

In an embodiment, the second thickness is smaller than the first thickness. In an embodiment, the depositing the first high-k dielectric layers comprises an atomic layer deposition process. In an embodiment, the first portion that is thinner is the first topmost horizontal portion, and the second portion that is thicker is the first bottom horizontal portion. In an embodiment, the first sidewall portion has a same thickness as the first bottom horizontal portion.

In an embodiment, the method further comprises forming a second plurality of semiconductor nanostructures comprising a second lower semiconductor nanostructure; and a second topmost semiconductor nanostructure over the second lower semiconductor nanostructure; and depositing second high-k dielectric layers encircling the second plurality of semiconductor nanostructures, wherein a second topmost high-k dielectric layer of the second high-k dielectric layers encircling the second topmost semiconductor nanostructure comprises a second topmost horizontal portion overlapping the second topmost semiconductor nanostructure; and a second bottom horizontal portion overlapped by the second topmost semiconductor nanostructure, wherein the second topmost horizontal portion is thicker than the first topmost horizontal portion.

In an embodiment, the second bottom horizontal portion is thinner than the second topmost horizontal portion. In an embodiment, the first portion is the first sidewall portion, and the second portion is the first bottom horizontal portion. In an embodiment, the method further comprises forming a source/drain region aside of and contacting the first plurality of semiconductor nanostructures; and forming a gate electrode over the first high-k dielectric layers. In an embodiment, the first high-k dielectric layers comprise hafnium oxide. In an embodiment, the interfacial layers comprise silicon oxide.

In accordance with some embodiments of the present disclosure, a method comprises forming a first plurality of semiconductor nanostructures comprising a first topmost semiconductor nanostructure; forming a second plurality of semiconductor nanostructures comprising a second topmost semiconductor nanostructure; depositing a first high-k dielectric layer encircling the first topmost semiconductor nanostructure, wherein the first high-k dielectric layer is deposited using first process conditions; and depositing a second high-k dielectric layer encircling the second topmost semiconductor nanostructure, wherein the second high-k dielectric layer is deposited using second process conditions different from the first process conditions, and wherein the first high-k dielectric layer comprises a same high-k dielectric material as the second high-k dielectric layer; forming a first gate electrode encircling the first high-k dielectric layer; and forming a second gate electrode encircling the second high-k dielectric layer, wherein the first gate electrode and the second gate electrode are formed sharing common processes.

In an embodiment, the method further comprises, before the first high-k dielectric layer is formed, forming a first interfacial layer over the first topmost semiconductor nanostructure; and before the second high-k dielectric layer is formed, forming a second interfacial layer over the second topmost semiconductor nanostructure, wherein the first interfacial layer is formed in a same formation process as the second interfacial layer.

In an embodiment, the first process conditions comprise a first wafer temperature and a first chamber pressure, and the second process conditions comprise a second wafer temperature higher than the first wafer temperature; and a second chamber pressure higher than the first chamber pressure. In an embodiment, the first high-k dielectric layer comprises a first topmost horizontal portion overlapping the first topmost semiconductor nanostructure; and a first bottom horizontal portion overlapped by the first topmost semiconductor nanostructure, wherein the first topmost horizontal portion is thinner than the first bottom horizontal portion.

In an embodiment, the second high-k dielectric layer comprises a second topmost horizontal portion overlapping the second topmost semiconductor nanostructure; and a second bottom horizontal portion overlapped by the second topmost semiconductor nanostructure, wherein the second topmost horizontal portion is thicker than the second bottom horizontal portion. In an embodiment, both of the first high-k dielectric layer and the second high-k dielectric layer are deposited through atomic layer deposition processes.

In accordance with some embodiments of the present disclosure, a structure comprises a first plurality of semiconductor nanostructures comprising a first lower semiconductor nanostructure; and a first topmost semiconductor nanostructure over the first lower semiconductor nanostructure; an interfacial layer encircling the first topmost semiconductor nanostructure; and a first high-k dielectric layer encircling the interfacial layer, wherein the first high-k dielectric layer comprises a first upper horizontal portion overlapping the first topmost semiconductor nanostructure and having a first thickness; a first bottom horizontal portion overlapped by the first topmost semiconductor nanostructure and having a second thickness different from the first thickness; and a first sidewall portion on a sidewall of the first topmost semiconductor nanostructure.

In an embodiment, the first thickness is smaller than the second thickness. In an embodiment, the structure further comprises a second plurality of semiconductor nanostructures comprising a second lower semiconductor nanostructure; and a second topmost semiconductor nanostructure over the second lower semiconductor nanostructure; and a second high-k dielectric layer encircling the second topmost semiconductor nanostructure, wherein the second high-k dielectric layer comprises a second upper horizontal portion overlapping the second topmost semiconductor nanostructure and having a third thickness; and a second bottom horizontal portion overlapped by the second topmost semiconductor nanostructure and having a fourth thickness smaller than the third thickness. In an embodiment, the first upper horizontal portion thinner than the first sidewall portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first plurality of semiconductor nanostructures comprising:
a first lower semiconductor nanostructure; and
a first topmost semiconductor nanostructure over the first lower semiconductor nanostructure;
forming interfacial layers on the first plurality of semiconductor nanostructures; and
depositing first high-k dielectric layers encircling the interfacial layers, wherein a first topmost high-k dielectric layer of the first high-k dielectric layers encircling the first topmost semiconductor nanostructure comprises:
a first topmost horizontal portion overlapping the first topmost semiconductor nanostructure;
a first bottom horizontal portion overlapped by the first topmost semiconductor nanostructure; and
a first sidewall portion on a sidewall of the first topmost semiconductor nanostructure, wherein a first portion selected from the first topmost horizontal portion, the first bottom horizontal portion, and the first sidewall portion has a first thickness, and a second portion selected from the first topmost horizontal portion, the first bottom horizontal portion, and the first sidewall portion has a second thickness different from the first thickness.

2. The method of claim 1, wherein the second thickness is smaller than the first thickness.

3. The method of claim 1, wherein the first portion that is thinner is the first topmost horizontal portion, and the second portion that is thicker is the first bottom horizontal portion.

4. The method of claim 3, wherein the first sidewall portion has a same thickness as the first bottom horizontal portion.

5. The method of claim 3 further comprising:
forming a second plurality of semiconductor nanostructures comprising:
a second lower semiconductor nanostructure; and
a second topmost semiconductor nanostructure over the second lower semiconductor nanostructure; and
depositing second high-k dielectric layers encircling the second plurality of semiconductor nanostructures, wherein a second topmost high-k dielectric layer of the second high-k dielectric layers encircling the second topmost semiconductor nanostructure comprises:
a second topmost horizontal portion overlapping the second topmost semiconductor nanostructure; and
a second bottom horizontal portion overlapped by the second topmost semiconductor nanostructure, wherein the second topmost horizontal portion is thicker than the first topmost horizontal portion.

6. The method of claim 5, wherein the second bottom horizontal portion is thinner than the second topmost horizontal portion.

7. The method of claim 1, wherein the first portion is the first sidewall portion, and the second portion is the first bottom horizontal portion.

8. The method of claim 1 further comprising:
forming a source/drain region aside of and contacting the first plurality of semiconductor nanostructures; and
forming a gate electrode over the first high-k dielectric layers.

9. The method of claim 1, wherein the first high-k dielectric layers comprise hafnium oxide.

10. The method of claim 1, wherein the interfacial layers comprise silicon oxide.

11. A method comprising:
forming a first plurality of semiconductor nanostructures comprising a first topmost semiconductor nanostructure;
forming a second plurality of semiconductor nanostructures comprising a second topmost semiconductor nanostructure;
depositing a first high-k dielectric layer encircling the first topmost semiconductor nanostructure, wherein the first high-k dielectric layer is deposited using first process conditions; and
depositing a second high-k dielectric layer encircling the second topmost semiconductor nanostructure, wherein the second high-k dielectric layer is deposited using second process conditions different from the first process conditions, and wherein the first high-k dielectric layer comprises a same high-k dielectric material as the second high-k dielectric layer;
forming a first gate electrode encircling the first high-k dielectric layer; and
forming a second gate electrode encircling the second high-k dielectric layer, wherein the first gate electrode and the second gate electrode are formed sharing common processes.

12. The method of claim 11 further comprising
before the first high-k dielectric layer is formed, forming a first interfacial layer over the first topmost semiconductor nanostructure; and
before the second high-k dielectric layer is formed, forming a second interfacial layer over the second topmost semiconductor nanostructure, wherein the first interfacial layer is formed in a same formation process as the second interfacial layer.

13. The method of claim 11, wherein the first process conditions comprise a first wafer temperature and a first chamber pressure, and the second process conditions comprise:
a second wafer temperature higher than the first wafer temperature; and
a second chamber pressure higher than the first chamber pressure.

14. The method of claim 13, wherein the first high-k dielectric layer comprises:
a first topmost horizontal portion overlapping the first topmost semiconductor nanostructure; and
a first bottom horizontal portion overlapped by the first topmost semiconductor nanostructure, wherein the first topmost horizontal portion is thinner than the first bottom horizontal portion.

15. The method of claim 14, wherein the second high-k dielectric layer comprises:
a second topmost horizontal portion overlapping the second topmost semiconductor nanostructure; and
a second bottom horizontal portion overlapped by the second topmost semiconductor nanostructure, wherein the second topmost horizontal portion is thicker than the second bottom horizontal portion.

16. The method of claim 11, wherein both of the first high-k dielectric layer and the second high-k dielectric layer are deposited through atomic layer deposition processes.

17. A structure comprising:
a first plurality of semiconductor nanostructures comprising:
a first lower semiconductor nanostructure; and
a first topmost semiconductor nanostructure over the first lower semiconductor nanostructure;
an interfacial layer encircling the first topmost semiconductor nanostructure; and
a first high-k dielectric layer encircling the interfacial layer, wherein the first high-k dielectric layer comprises:
a first upper horizontal portion overlapping the first topmost semiconductor nanostructure and having a first thickness;
a first bottom horizontal portion overlapped by the first topmost semiconductor nanostructure and having a second thickness different from the first thickness; and
a first sidewall portion on a sidewall of the first topmost semiconductor nanostructure.

18. The structure of claim 17, wherein the first thickness is smaller than the second thickness.

19. The structure of claim 18 further comprising:
a second plurality of semiconductor nanostructures comprising:
a second lower semiconductor nanostructure; and
a second topmost semiconductor nanostructure over the second lower semiconductor nanostructure; and
a second high-k dielectric layer encircling the second topmost semiconductor nanostructure, wherein the second high-k dielectric layer comprises:
a second upper horizontal portion overlapping the second topmost semiconductor nanostructure and having a third thickness; and
a second bottom horizontal portion overlapped by the second topmost semiconductor nanostructure and having a fourth thickness smaller than the third thickness.

20. The structure of claim 18, wherein the first upper horizontal portion thinner than the first sidewall portion.
